(19) United States
(12) Patent Application Publication
(10) Pub. No.: US 2026/0123203 A1
(43) Pub. Date: Apr. 30, 2026

(54) DISPLAY PANEL AND DISPLAY DEVICE

(71) Applicant: HKC CORPORATION LIMITED, SHENZHEN (CN)

(72) Inventors: Zhonglin CAO, SHENZHEN (CN); Lidan YE, SHENZHEN (CN)

(73) Assignee: HKC CORPORATION LIMITED, SHENZHEN (CN)

(21) Appl. No.: 19/356,124

(22) Filed: Oct. 12, 2025

(30) Foreign Application Priority Data
Oct. 31, 2024 (CN) 202411547281.2

(51) Int. Cl. H10K 59/127; H10K 59/122; H10K 59/80; H10K 102/10

(52) U.S. Cl. CPC H10K 59/1275; H10K 59/122; H10K 59/80518; H10K 59/80524; H10K 59/873; H10K 2102/102; H10K 2102/103

(57) ABSTRACT

A display panel and a display device. The display panel includes a silicon-based drive substrate and a light-emitting substrate, where the light-emitting substrate is connected to the silicon-based drive substrate. The light-emitting substrate includes a glass substrate, a first light-emitting device, and a second light-emitting device, where the glass substrate is spaced apart from the silicon-based drive substrate; the first light-emitting device is disposed on a side of the glass substrate away from the silicon-based drive substrate; the second light-emitting device is disposed between the silicon-based drive substrate and the glass substrate.

### CROSS-REFERENCE TO RELATED APPLICATIONS

The present application claims priority of Chinese Patent Application No. 202411547281.2, filed on October 31, 2024, the entire contents of which are hereby incorporated by reference in their entirety.

### TECHNICAL FIELD

The present disclosure relates to the field of display technologies, and in particular to a display panel and a display device.

### BACKGROUND

Organic Light Emitting Diode (OLED), also referred to as Organic Electroluminesence Display (OELD), represents a cutting-edge advancement in display technology. Its advantages, such as superior contrast ratios, wide viewing angles, flexibility, lightweight design, and energy efficiency, surpass those of traditional liquid crystal displays (LCDs), making OLED a widely adopted and promising direction in modern display innovation.

However, the luminous brightness of existing OLED display panels are still required to be further improved.

### SUMMARY OF THE DISCLOSURE

The present disclosure provides a display panel, including:

a silicon-based drive substrate; and

a light-emitting substrate, connected to the silicon-based drive substrate; wherein the light-emitting substrate includes:

a glass substrate, spaced apart from the silicon-based drive substrate;

a first light-emitting device, disposed on a side of the glass substrate away from the silicon-based drive substrate; and

a second light-emitting device, disposed between the silicon-based drive substrate and the glass substrate.

The present disclosure further provides a display device, including the display panel as above.

### BRIEF DESCRIPTION OF THE DRAWINGS

To more clearly illustrate the technical solutions of the embodiments of the present disclosure, the following is a brief introduction to the drawings used in the description of the embodiments. It should be understood that the drawings described below are merely some embodiments of the present disclosure. For those skilled in the art, other drawings can be obtained without any creative effort based on these drawings.

FIG. 1 is a structural schematic view of a display device according to some embodiments of the present disclosure.

FIG. 2 is a first structural schematic view of a display panel according to some embodiments of the present disclosure.

FIG. 3 is a second structural schematic view of a display panel according to some embodiments of the present disclosure.

### DETAILED DESCRIPTION

The technical solutions in the embodiments of the present disclosure will be described in detail with reference to the accompanying drawings. The following embodiments are provided solely to illustrate the technical solutions of the present disclosure and are therefore only examples and should not be intended to limit the scope of the present disclosure.

Unless otherwise defined, all technical and scientific terms used herein have the same meanings as generally understood by those skilled in the art to which the present disclosure relates. The terms used herein are intended to describe specific embodiments and are not intended to limit the present disclosure. The terms “include” and “have” and any variations thereof used in the description, claims, and accompanying drawings of the present disclosure are intended to cover non-exclusive inclusion.

In the description of the embodiments of the present disclosure, the technical terms “first”, “second”, etc. are only intended to distinguish different objects, and are not to be construed as indicating or implying relative importance, or implicitly specifying the number, specific order, or primary and secondary relationship of the technical features indicated. In the description of the embodiments of the present disclosure, “more than one” means more than two, unless otherwise expressly and specifically limited.

Reference to “embodiments” herein implies that a particular feature, structure, or characteristic described in conjunction with an embodiment may be included in at least one embodiment of the present disclosure. The presence of the phrase at various points in the specification does not necessarily refer to the same embodiments or to separate or alternative embodiments that are mutually exclusive of other embodiments. It is understood by those skilled in the art, both explicitly and implicitly, that the embodiments described herein may be combined with other embodiments.

In the description of embodiments of the present disclosure, the term “and/or” is merely an associative relationship describing an associated object, indicating that three types of relationships may exist, such as A and/or B, which may indicate: the existence of A alone, the existence of both A and B, and the existence of B alone. In addition, the character “/” herein generally indicates that the associated objects are in an “or” relationship.

In the description of the embodiments of the present disclosure, the term “plurality” refers to more than two (including two), and similarly, “multiple groups” refers to more than two (including two), and “multiple tablets” refers to more than two (including two).

In the description of embodiments of the present disclosure, the technical terms “center”, “longitudinal”, “transverse”, “length”, “width”, “thickness”, “up”, “down”, “front”, “rear”, “left”, “right”, “vertical”, “horizontal”, “top”, “bottom”, “inside”, “outside”, “clockwise”, “counterclockwise”, “axial”, “radial”, “peripheral”, etc. indicate orientations or positional relationships based on those shown in the accompanying drawings, and are intended only to facilitate the description of the embodiments of the present disclosure and to simplify the description, and are not intended to indicate or imply that the device or element referred to must have a particular orientation, be constructed and operated with a particular orientation, and therefore are not to be construed as a limitation of the embodiments of the present disclosure.

In the description of the embodiments of the present disclosure, unless otherwise expressly provided and limited, the technical terms “mounted”, “connected”, “coupled”, “fixed”, and the like shall be understood in a broad sense, for example, it may be a fixed connection, a detachable connection, or a one-piece connection; it may be a mechanical connection, or an electrical connection; it may be a direct connection, or an indirect connection through an intermediate medium, and it may be a connectivity within the two elements or an interactive relationship between the two elements. For those skilled in the art, the specific meanings of the above terms in the embodiments of the present disclosure may be understood on a case-by-case basis.

Organic Light Emitting Diode (OLED), also referred to as Organic Electroluminesence Display (OELD), represents a cutting-edge advancement in display technology. Its advantages, such as superior contrast ratios, wide viewing angles, flexibility, lightweight design, and energy efficiency, surpass those of traditional liquid crystal displays (LCDs), making OLED a widely adopted and promising direction in modern display innovation.

However, the luminous brightness of existing OLED display panels are still required to be further improved.

The present disclosure provides a display device, and the display device may include, but is not limited to, a mobile phone, a tablet, a laptop, a desktop, a terminal, an interactive display, a digital audio/video device, an Internet of Things (IoT) device, and the like. The interactive display may include an interactive whiteboard, a digital advertising interactive screen, and a gaming interactive display, etc. The IoT device may include a smart home device and a smart wearable device, etc. The display device may include a display panel, and the display device may achieve functions such as displaying images through the display panel.

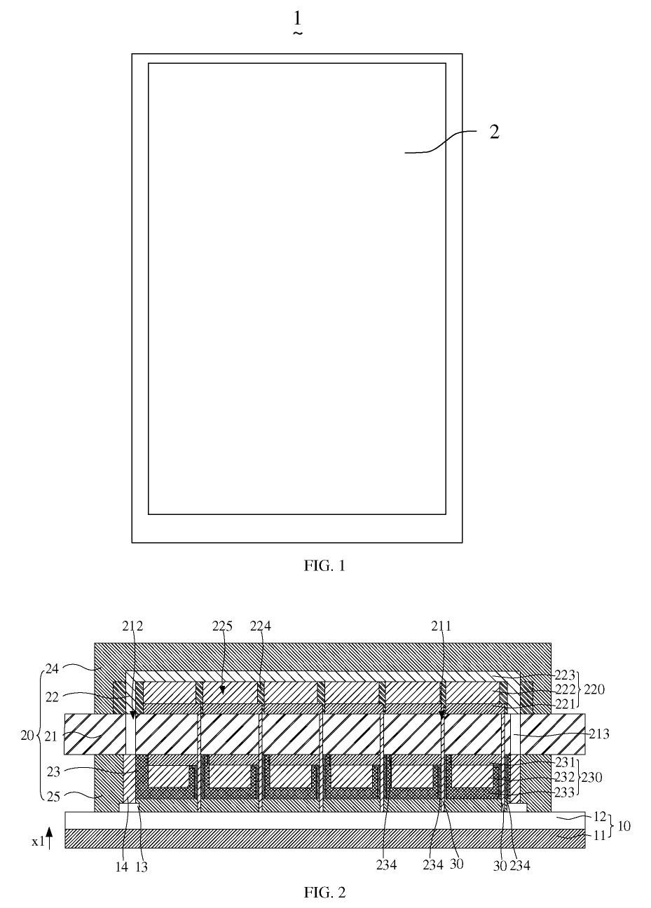

Referring to FIG. 1, FIG. 1 is a structural schematic view of a display device according to some embodiments of the present disclosure.

The display device 1 may be, but is not limited to, a mobile phone, a computer, etc., where the mobile phone may be an ordinary mobile phone, a feature phone, or a smartphone, and the smartphone may be a flat-screen phone, a curved-screen phone, or a foldable phone, etc. The display device 1 is arranged with a display panel 2, and the display panel 2 may be disposed on a head portion or a middle portion or a tail portion of the display device 1. The display panel 2 may be configured to display information of the display device 1, for example, the display panel 2 may serve as a visual information display portion of the display device 1. The display panel 2 may further serve as a touch information input portion, for facilitating a user’s operation of the display device 1 by means of touching the display panel 2, e.g., for realizing the displaying and inputting requirements for interface navigation and function switching of the display device 1.

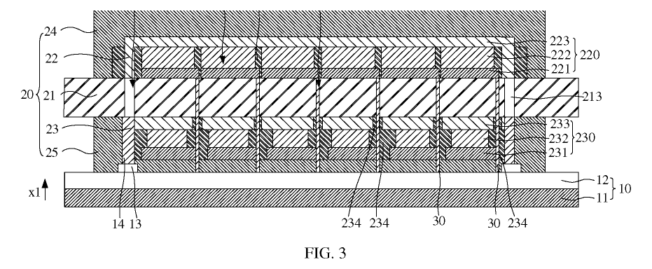

Referring to FIG. 2, FIG. 2 is a first structural schematic view of a display panel according to some embodiments of the present disclosure.

To solve the above problems, the present disclosure provides a display panel 2, including: a silicon-based drive substrate 10 and a light-emitting substrate 20. The light-emitting substrate 20 is connected to the silicon-based drive substrate 10; the light-emitting substrate 20 includes a glass substrate 21, a first light-emitting device 22, and a second light-emitting device 23, where the glass substrate 21 is spaced apart from the silicon-based drive substrate 10; the first light-emitting device 22 is disposed on a side of the glass substrate 21 away from the silicon-based drive substrate 10; the second light-emitting device 23 is disposed between the silicon-based drive substrate 10 and the glass substrate 21.

The light-emitting substrate 20 may be connected to the silicon-based drive substrate 10. The light-emitting substrate 20 includes the glass substrate 21, the first light-emitting device 22, and the second light-emitting device 23. The first light-emitting device 22 and the second light-emitting device 23 are both capable of emitting light beams, and the light beams emitted by the first light-emitting device 22 and the second light-emitting device 23 may be emitted in a direction away from the silicon-based drive substrate 10. The silicon-based drive substrate 10 may include a silicon substrate 11 and a drive circuit layer 12, with the drive circuit layer 12 disposed on a side of the silicon substrate 11 close to the glass substrate 21.

The silicon-based substrate 11 refers to a substrate plate based on a monocrystalline silicon material.

The drive circuit layer 12 includes an active drive circuit (not shown) integrated on the silicon-based substrate 11 using a Complementary Metal-Oxide-Semiconductive wire (CMOS) process.

In the fabrication process, the silicon-based drive substrate 10 is prepared separately from the light-emitting substrate 20, which may improve the production efficiency and further avoid the effect of the vapor deposition process on the silicon-based drive substrate 10, reducing the loss of the silicon-based drive substrate 10. In other words, from a process perspective, the separate preparation of the silicon-based drive substrate 10 and the light-emitting substrate 20 may not only improve the yield, but also reduce the cost.

In addition, during the preparation process of the light-emitting substrate 20, one of the first light-emitting device 22 and the second light-emitting device 23 can be first fabricated on a side of the glass substrate 21, and then the other of the first light-emitting device 22 and the second light-emitting device 23 can be fabricated on the other side of the glass substrate 21. After separately fabricating the light-emitting substrate 20 and the silicon-based drive substrate 10, the light-emitting substrate 20 and the silicon-based drive substrate 10 are connected together. It should be understood that the glass substrate 21 can provide fixation and support for the first light-emitting device 22 and the second light-emitting device 23, and no drive circuit is required to be provided on the glass substrate 21. Therefore, there is no risk of damaging the drive circuit when fabricating the first light-emitting device 22 and the second light-emitting device 23 on the glass substrate 21. By separately preparing the light-emitting substrate 20, which includes the first light-emitting device 22 and the second light-emitting device 23, and the silicon-based drive substrate 10 and connecting them together, the first light-emitting device 22 and the second light-emitting device 23 are not required to be directly fabricated on the silicon-based drive substrate 10, which may further reduce the impact on drive circuits in the silicon-based drive substrate 10 during the vapor deposition of the first light-emitting device 22 and the second light-emitting device 23, thereby minimizing losses caused by errors in subsequent processes and lowering the manufacturing cost of the silicon-based drive substrate 10.

The silicon-based drive substrate 10 may be configured to drive the first light-emitting device 22 and the second light-emitting device 23. It should be noted that the first light-emitting device 22 and the second light-emitting device 23 may be electrically connected to the silicon-based drive substrate 10 separately, enabling the silicon-based drive substrate 10 to drive the first light-emitting device 22 and the second light-emitting device 23 to emit light independently. In this context, the silicon-based drive substrate 10 driving the first light-emitting device 22 and the second light-emitting device 23 to emit light independently may refer to the first light-emitting device 22 and the second light-emitting device 23 each having their own corresponding anode and cathode, and the silicon-based drive substrate 10 can drive the anodes and cathodes corresponding to each of the two light-emitting devices to independently illuminate the first light-emitting device 22 and the second light-emitting device 23. In some application scenarios, the silicon-based drive substrate 10 may drive the first light-emitting device 22 and the second light-emitting device 23 to emit light simultaneously, thereby enhancing the brightness of the display panel 2.

In some application scenarios, the second light-emitting device 23 may be directly connected to the silicon-based drive substrate 10, while the first light-emitting device 22 may be directly or indirectly connected to the silicon-based drive substrate 10. For example, the first light-emitting device 22 may be electrically connected to the drive circuit layer 12 through a through hole on the glass substrate 21 by means of drilling holes on the glass substrate 21. Specifically, the anode of the second light-emitting device 23 may be directly electrically connected to the silicon-based drive substrate 10, and the anode of the first light-emitting device 22 may be directly electrically connected to the silicon-based drive substrate 10 through the through hole on the glass substrate 21; or, the anode of the first light-emitting device 22 may be electrically connected to the anode of the second light-emitting device 23 through the through hole on the glass substrate 21, thereby achieving an indirect electrical connection to the silicon-based drive substrate 10.

It should be understood that the glass through-hole technology has the advantages of excellent high-frequency electrical characteristics, low cost, simple process flow, and high mechanical stability compared to the silicon through-hole technology.

Through the above-described implementations, the glass substrate 21 can provide fixation and support for the first light-emitting device 22 and the second light-emitting device 23, and the silicon-based drive substrate 10 provides further support and fixation for the glass substrate 21, the first light-emitting device 22, and the second light-emitting device 23. In addition, the silicon-based drive substrate 10 can simultaneously drive the first light-emitting device 22 and the second light-emitting device 23, thereby enabling the first light-emitting device 22 and the second light-emitting device 23 to emit light beams simultaneously, thereby improving the brightness of the display panel 2. Additionally, the light-emitting substrate 20 and the silicon-based drive substrate 10 can be prepared separately, thereby reducing losses caused by errors in subsequent processes and lowering the manufacturing cost of the display panel 2.

In some embodiments, the first light-emitting device 22 includes multiple first subpixels 220, each of which includes a first anode 221, a first light-emitting layer 222, and a first cathode 223 that are stacked in a direction away from the glass substrate 21. The first anode 221 and the first cathode 223 are both transparent electrodes. The first anode 221 and the first cathode 223 can achieve an electrical connection to the first light-emitting layer 222 to cause the first light-emitting layer 222 to emit light beams. The first light-emitting layers 222 of the multiple first subpixels 220 have different colors, and each first light-emitting layer 222 emits one of red light, blue light, or green light when energized. It should be noted that the first anodes 221 of the multiple first subpixels 220 are spaced apart from each other, the first cathodes 223 are planar cathodes (i.e., the first cathodes 223 can form an integral cathode), and the first cathodes 223 of the multiple first subpixels 220 are electrically connected to each other. Additionally, the first cathodes 223 may be connected to the silicon-based drive substrate 10 via methods including but not limited to drilling holes in the glass substrate 21. As a result, the first anodes 221 and the first cathodes 223 are transparent electrodes, facilitating the emission of light beams from the first light-emitting layer 222 outward. It can be understood that the light beams emitted by the second light-emitting device 23 can sequentially transmit through the first anode 221 and the first cathode 223 and emit outward, thereby reducing the obstruction of the light beams emitted by the second light-emitting device 23 by the cathode and anode of the first light-emitting device 22, and thus improving the brightness of the display panel 2.

In some embodiments, the glass substrate 21 defines a first through hole 211 that extends through opposite surfaces of the glass substrate 21. The display panel 2 further includes a conductive wire 30, which passes through the first through hole 211 and is electrically connected to the first light-emitting device 22 and the second light-emitting device 23, respectively. The conductive wire 30 extends in a direction perpendicular to the glass substrate 21 and the silicon-based drive substrate 10, to reach the silicon-based drive substrate 10 and be electrically connected to the silicon-based drive substrate 10. The conductive wire 30 may be a metal wire. For example, the conductive wire 30 may be configured to connect the first anode 221 and the anode of the second light-emitting device 23, or it may be used to connect the first cathode 223 and the cathode of the second light-emitting device 23. It should be understood that the silicon-based drive substrate 10 is electrically connected to both the first light-emitting device 22 and the second light-emitting device 23 via the conductive wire 30, enabling both the first light-emitting device 22 and the second light-emitting device 23 to emit light beams simultaneously through the conductive wire 30.

In some embodiments, as shown in FIG. 2, the second light-emitting device 23 includes multiple second subpixels 230, each of which includes a second anode 231, a second light-emitting layer 232, and a second cathode 233 that are stacked in a direction of the glass substrate 21 toward the silicon-based drive substrate 10. The second anode 231 is a transparent electrode, the second cathode 233 is a reflective electrode, and the second cathode 233 is configured to reflect the light beams emitted by the first light-emitting layer 222 and the second light-emitting layer 232. The second anode 231 and the second cathode 233 can achieve an electrical connection to the second light-emitting layer 232 to cause the second light-emitting layer 232 to emit light beams. The colors of the second light-emitting layers 232 of the multiple second subpixels 230 are different, and each second light-emitting layer 232 emits one of red light, blue light, or green light when energized. It should be noted that the color of the light beam emitted by each second light-emitting layer 232 is the same as the color of the light beam emitted by a corresponding first light-emitting layer 222 in a light-emitting direction x1 of the display panel 2. It can be understood that the light beam emitted by the second light-emitting layer 232 along the light-emitting direction x1 of the display panel 2 can sequentially pass through the second anode 231, the first anode 221, and the second anode 231 and be emitted outward. It should be noted that at least part of each of the light beams emitted by the first light-emitting layer 222 and the second light-emitting layer 232 is emitted in an opposite direction of the light-emitting direction x1 of the display panel 2. These light beams emitted in the opposite direction can be reflected by the second cathode 233 of the second subpixel 230 back toward the light emission direction x1 and emitted outward. For example, the light beam emitted in the opposite direction by the first light-emitting layer 222 can sequentially pass through the first anode 221 and the second anode 231 and be received by the second cathode 233 and reflected back toward the light emission direction x1 for emission. The light beam emitted in the opposite direction by the second light-emitting layer 232 can be directly received by the second cathode 233 and reflected toward the light emission direction x1 for emission. The second cathode 233 may be a metal electrode, and the material of the second cathode 233 may include but is not limited to chromium, titanium, gold, silver, copper, aluminum, ITO, their combinations, or other suitable conductive materials. As a result, the second cathode 233 can reflect the light beams emitted by the first light-emitting layer 222 and the second light-emitting layer 232 in the opposite direction of the light emission direction x1 of the display panel 2 back to the light emission direction x1, thereby reducing brightness loss and further improving the brightness of the display panel 2. It should be noted that the second anodes 231 of multiple second subpixels 230 are arranged at intervals, the second cathodes 233 form a planar cathode and are electrically connected to the first cathode 223, meaning that the second cathodes 233 of the multiple second subpixels 230 are electrically connected to each other. The first cathode 223 and the second cathode 233 may be electrically connected in various ways. For example, the first cathode 223 and the second cathode 233 may be electrically connected by drilling holes in the glass substrate 21; or the first cathode 223 and the second cathode 233 may be electrically connected via a silver paste process. It should be understood that the first cathode 223 and the second cathode 233 may be electrically connected via other methods.

The connection methods between the first anode 221 and the second anode 231 and the silicon-based drive substrate 10 may also be various. For example, the first anode 221 and the second anode 231 may be electrically connected to each other via the conductive wire 30, and then electrically connected to the silicon-based drive substrate 10 via the conductive wire 30. Alternatively, in other embodiments, the first anode 221 may be electrically connected to the silicon-based drive substrate 10 via a hole drilled in the glass substrate 21 independently, and the second cathode 233 may be electrically connected to the silicon-based drive substrate 10 independently. In the illustrated embodiments, the first anode 221 and the second cathode 233 are electrically connected to each other via the conductive wire 30 and are electrically connected to the silicon-based drive substrate 10. This allows the silicon-based drive substrate 10 to simultaneously drive the first anode 221 and the second cathode 233 via the conductive wire 30, causing the first light-emitting layer 222 and the second light-emitting layer 232 to emit light simultaneously, thereby enhancing the brightness of the display panel 2. In other embodiments, the second anode 231 may define a recess with an opening facing the light emission direction x1, and the second light-emitting layer 232 is at least partially accommodated within the recess, enabling the reflective electrode to receive light beams emitted from the second light-emitting layer 232 from multiple angles and reflect them toward the light emission direction x1, thereby improving the brightness of the display panel 2.

In some embodiments, the glass substrate 21 defines a second through hole 212 that extends through the opposite surfaces of the glass substrate 21. The second through hole 212 is spaced apart from the first through hole 211, and the second through hole 212 is filled with a conductive portion 213. The second cathode 233 and the first cathode 223 are electrically connected via the conductive portion 213. The second through hole 212 may serve as a cathode conductive hole, and the first cathode 223 and the second cathode 233 may be electrically connected to each other through the second through hole 212 and connected to the silicon-based drive substrate 10. The second through hole 212 may be prepared using Through-Glass Via (TGV) technology. Specifically, the conductive portion 213 may be a conductive material filled within the second through hole 212. The conductive material within the second through hole 212 is not limited herein and may be selected according to actual requirements. The second through hole 212 passes through the glass substrate 21 in a direction perpendicular to the glass substrate 21. In some application scenarios, the drive circuit layer 12 further includes a cathode 13, and a side of the glass substrate 21 close to the silicon-based drive substrate 10 further includes a cathode extension electrode 14. The cathode 13 is correspondingly arranged and electrically connected to the cathode extension electrode 14. The second through hole 212 is arranged corresponding to the cathode extension electrode 14 and electrically connected thereto. The first cathode 223 is electrically connected to the conductive portion 213, and the second cathode 233 is electrically connected to the cathode extension electrode 14, thereby connecting the first cathode 223 and the second cathode 233 to each other and electrically connecting them to the silicon-based drive substrate 10.

In other embodiments, the second through hole 212 may be electrically connected to the drive circuit layer 12 through other means.

In some embodiments, the second light-emitting device 23 further includes an insulating portion 234; the insulating portion 234 is filled between the second cathode 233 and the conductive wire 30, and/or, the insulating portion 234 is filled between the second cathode 233 and the second anode 231. The insulating portion 234, which is filled between the second cathode 233 and the conductive line 30, may reduce the risk of a short circuit between the second cathode 233 and the conductive line 30. In some applications, the second cathode 233 defines a recess with an opening facing the light-emitting direction x1, and the insulating portion 234 may be filled between the second cathode 233 and the second anode 231, thereby reducing the risk of a short circuit between the second cathode 233 and the second anode 231 through the insulating portion 234. As a result, the risk of a short circuit between the second cathode 233 and the conductive wire 30 and the second anode 231 may be reduced through the insulating portion 234, thereby improving the reliability of the display panel 2.

In some embodiments, the first light-emitting device 22 further includes a pixel definition layer 224, which protrudes from the glass substrate 21 and defines a pixel accommodation region 225, with the multiple first subpixels 220 arranged within the pixel accommodation region 225. The pixel definition layer 224 limits the positions of the first subpixels 220 through the pixel accommodation regions 225, thereby ensuring that the first subpixels 220 are positioned appropriately. The material of the pixel definition layer 224 may be an organic material, an organic material with an inorganic coating thereon, or an inorganic material. The organic material of the pixel definition layer 224 includes, but is not limited to, polyimide. The inorganic material of the pixel definition layer 224 includes, but is not limited to, silicon dioxide (SiO), silicon nitride (SiN), silicon oxynitride (SiNO), magnesium fluoride (MgF), or combinations thereof. The specific material of the pixel definition layer 224 is not limited, and it may be selected according to actual requirements. In this way, the pixel definition layer 224 may isolate adjacent first subpixels 220, thereby reducing the risk of crosstalk between the first subpixels 220.

In some embodiments, the light-emitting substrate 20 further includes a first encapsulation layer 24 and a second encapsulation layer 25. The first encapsulation layer 24 covers a side of the first light-emitting device 22 away from the glass substrate 21 and a side wall of the first light-emitting device 22, while the second encapsulation layer 25 covers at least a side wall of the second light-emitting device 23. The first encapsulation layer 24 and the second encapsulation layer 25 may be configured to protect the first light-emitting device 22 and the second light-emitting device 23 from external moisture and other contaminants that could damage the first light-emitting device 22 and the second light-emitting device 23. The material of the encapsulation layer is not limited and may be selected according to actual requirements.

Referring to FIG. 3, FIG. 3 is a second structural schematic view of a display panel according to some embodiments of the present disclosure.

In some embodiments, as shown in FIG. 3, the second light-emitting device 23 includes multiple second subpixels 230, each of which includes a second cathode 233, a second light-emitting layer 232, and a second anode 231 that are stacked in a direction of the glass substrate 21 toward the silicon-based drive substrate 10. The second cathode 233 is a transparent electrode, the second anode 231 is a reflective electrode, and the second anode 231 is configured to reflect the light beams emitted by the first light-emitting layer 222 and the second light-emitting layer 232. The second cathode 233 and the second anode 231 can achieve an electrical connection to the second light-emitting layer 232 to cause the second light-emitting layer 232 to emit light beams. The colors of the second light-emitting layers 232 of the multiple second subpixels 230 are different, and each second light-emitting layer 232 emits one of red light, blue light, or green light when energized. It should be noted that the color of the light beam emitted by each second light-emitting layer 232 is the same as the color of the light beam emitted by a corresponding first light-emitting layer 222 in a light-emitting direction x1 of the display panel 2. It can be understood that the light beam emitted by the second light-emitting layer 232 along the light-emitting direction x1 of the display panel 2 can sequentially pass through the second cathode 233, the first anode 221, and the second cathode 233 and be emitted outward. It should be noted that at least part of each of the light beams emitted by the first light-emitting layer 222 and the second light-emitting layer 232 is emitted in an opposite direction of the light-emitting direction x1 of the display panel 2. These light beams emitted in the opposite direction can be reflected by the second anode 231 of the second subpixel 230 and emitted outward in the light emission direction x1. For example, the light beam emitted in the opposite direction by the first light-emitting layer 222 can sequentially pass through the first anode 221 and the second cathode 233, and be received by the second anode 231 and reflected back toward the light emission direction x1 for emission. The light beam emitted in the opposite direction by the second light-emitting layer 232 can be directly received by the second anode 231 and reflected toward the light emission direction x1 for emission. The second anode 231 may be a metal electrode, and the material of the second anode 231 may include but is not limited to chromium, titanium, gold, silver, copper, aluminum, ITO, their combinations, or other suitable conductive materials. As a result, the second anode 231 can reflect the light beams emitted by the first light-emitting layer 222 and the second light-emitting layer 232 in the opposite direction of the light emission direction x1 of the display panel 2 back to the light emission direction x1, thereby reducing brightness loss and further improving the brightness of the display panel 2. It should be noted that the second anodes 231 of the multiple second subpixels 230 are arranged at intervals, the second cathodes 233 form a planar cathode and are electrically connected to the first cathode 223, meaning that the second cathodes 233 of the multiple second subpixels 230 are electrically connected to each other. The first cathode 223 and the second cathode 233 may be electrically connected in various ways. For example, the first cathode 223 and the second cathode 233 may be electrically connected by drilling holes in the glass substrate 21. It should be understood that the first cathode 223 and the second cathode 233 may be electrically connected by other means.

The connection methods between the first anode 221 and the second anode 231 and the silicon-based drive substrate 10 may also be various. For example, the first anode 221 and the second anode 231 may be electrically connected to each other via the conductive wire 30, and then electrically connected to the silicon-based drive substrate 10 via the conductive wire 30. Alternatively, in other embodiments, the first anode 221 may be electrically connected to the silicon-based drive substrate 10 via a hole drilled in the glass substrate 21 independently, and the second anode 231 may be electrically connected to the silicon-based drive substrate 10 independently. In the illustrated embodiments, as shown in FIG. 3, the first anode 221 and the second anode 231 are electrically connected to each other via the conductive wire 30 and are electrically connected to the silicon-based drive substrate 10. As a result, the silicon-based drive substrate 10 can simultaneously drive the first anode 221 and the second anode 231 via the conductive wire 30, causing the first light-emitting layer 222 and the second light-emitting layer 232 to emit light simultaneously, thereby enhancing the brightness of the display panel 2.

In summary, the present disclosure provides a display panel 2, including a silicon-based drive substrate 10 and a light-emitting substrate 20, where the light-emitting substrate 20 is connected to the silicon-based drive substrate 10; the light-emitting substrate 20 includes a glass substrate 21, a first light-emitting device 22, and a second light-emitting device 23, where the glass substrate 21 is spaced apart from the silicon-based drive substrate 10; the first light-emitting device 22 is disposed on a side of the glass substrate 21 away from the silicon-based drive substrate 10; the second light-emitting device 23 is disposed between the silicon-based drive substrate 10 and the glass substrate 21. Through the above implementations, the glass substrate 21 provides fixation and support for the first light-emitting device 22 and the second light-emitting device 23, and the silicon-based drive substrate 10 provides further support and fixation for the glass substrate 21, the first light-emitting device 22, and the second light-emitting device 23. Further, the silicon-based drive substrate 10 can simultaneously drive the first light-emitting device 22 and the second light-emitting device 23, thereby enabling the first light-emitting device 22 and the second light-emitting device 23 to emit light beams simultaneously, thereby improving the brightness of the display panel 2.

Finally, it should be noted that the above embodiments are only intended to illustrate the technical solutions of the present disclosure, not to limit them. Although the present disclosure has been described in detail with reference to the foregoing embodiments, those skilled in the art should understand that he or she can still make modifications to the technical solutions documented in the foregoing embodiments, or make equivalent substitutions for some or all of the technical features therein. These modifications or substitutions do not detach the essence of the corresponding technical solutions from the scope of the technical solutions of the embodiments of the present disclosure, which shall be covered by the scope of the claims and the specification of the present disclosure. In particular, as long as there is no structural conflict, the technical features mentioned in the various embodiments can be combined in any way. The present disclosure is not limited to the particular embodiments disclosed herein, but includes all technical solutions falling within the scope of the claims.

1. A display panel, comprising:
a silicon-based drive substrate; and
a light-emitting substrate, connected to the silicon-based drive substrate; wherein the light-emitting substrate comprises:
a glass substrate, spaced apart from the silicon-based drive substrate;
a first light-emitting device, disposed on a side of the glass substrate away from the silicon-based drive substrate; and
a second light-emitting device, disposed between the silicon-based drive substrate and the glass substrate.

2. The display panel according to claim 1, wherein the first light-emitting device comprises a plurality of first subpixels; each of the plurality of first subpixels comprises a first anode, a first light-emitting layer, and a first cathode that are stacked in a direction away from the glass substrate; the first anode and the first cathode are both transparent electrodes.

3. The display panel according to claim 2, wherein the first anodes of the plurality of first subpixels are spaced apart from each other, and the first cathodes of the plurality of first subpixels form a planar cathode and are electrically connected to each other.

4. The display panel according to claim 2, wherein the glass substrate defines a first through hole that extends through opposite surfaces of the glass substrate; the display panel further comprises a conductive wire that passes through the first through hole and is electrically connected to the first light-emitting device and the second light-emitting device, respectively; the conductive wire extends in a direction perpendicular to the glass substrate and the silicon-based drive substrate, to reach the silicon-based drive substrate and be electrically connected to the silicon-based drive substrate.

5. The display panel according to claim 4, wherein the second light-emitting device comprises a plurality of second subpixels; each of the plurality of second subpixels comprises a second cathode, a second light-emitting layer, and a second anode that are stacked in a direction of the glass substrate toward the silicon-based drive substrate; the second cathode is a transparent electrode, the second anode is a reflective electrode, and the second anode is configured to reflect light beams emitted by the first light-emitting layer and the second light-emitting layer.

6. The display panel according to claim 4, wherein the second light-emitting device comprises a plurality of second subpixels; each of the plurality of second subpixels comprises a second anode, a second light-emitting layer, and a second cathode that are stacked in a direction of the glass substrate toward the silicon-based drive substrate; the second anode is a transparent electrode, the second cathode is a reflective electrode, and the second cathode is configured to reflect light beams emitted by the first light-emitting layer and the second light-emitting layer.

7. The display panel according to claim 6, wherein the second anodes of the plurality of second subpixels are spaced apart from each other, and the second cathodes of the plurality of first subpixels form a planar cathode and are electrically connected to each other.

8. The display panel according to claim 6, wherein a material of the second cathode comprises at least one of: chromium, titanium, gold, silver, copper, aluminum, and indium tin oxide (ITO).

9. The display panel according to claim 6, wherein the second anode defines a recess with an opening facing a light emission direction, and the second light-emitting layer is at least partially accommodated within the recess.

10. The display panel according to claim 6, wherein the glass substrate defines a second through hole that extends through the opposite surfaces of the glass substrate; the second through hole is spaced apart from the first through hole, and the second through hole is filled with a conductive portion; the second cathode and the first cathode are electrically connected via the conductive portion.

11. The display panel according to claim 10, wherein the silicon-based drive substrate comprises a silicon substrate and a drive circuit layer, with the drive circuit layer disposed on a side of the silicon substrate close to the glass substrate;
the drive circuit layer further comprises a cathode, and a side of the glass substrate close to the silicon-based drive substrate further comprises a cathode extension electrode; the cathode is electrically connected to the cathode extension electrode; the second through hole is arranged corresponding to the cathode extension electrode and electrically connected to the cathode extension electrode; the first cathode is electrically connected to the conductive portion, and the second cathode is electrically connected to the cathode extension electrode.

12. The display panel according to claim 10, wherein the second light-emitting device further comprises an insulating portion;
at least one of the following is satisfied:
the insulating portion is filled between the second cathode and the conductive wire, and, the insulating portion is filled between the second cathode and the second anode.

13. The display panel according to claim 2, wherein the first light-emitting device further comprises a pixel definition layer that protrudes from the glass substrate and defines a pixel accommodation region, with the plurality of first subpixels arranged within the pixel accommodation region.

14. The display panel according to claim 1, wherein the light-emitting substrate further comprises a first encapsulation layer and a second encapsulation layer; the first encapsulation layer covers a side of the first light-emitting device away from the glass substrate and a side wall of the first light-emitting device, and the second encapsulation layer covers at least a side wall of the second light-emitting device.

15. A display device, comprising a display panel; wherein the display panel comprises:
a silicon-based drive substrate; and
a light-emitting substrate, connected to the silicon-based drive substrate; wherein the light-emitting substrate comprises:
a glass substrate, spaced apart from the silicon-based drive substrate;
a first light-emitting device, disposed on a side of the glass substrate away from the silicon-based drive substrate; and
a second light-emitting device, disposed between the silicon-based drive substrate and the glass substrate.

16. The display device according to claim 15, wherein the first light-emitting device comprises a plurality of first subpixels; each of the plurality of first subpixels comprises a first anode, a first light-emitting layer, and a first cathode that are stacked in a direction away from the glass substrate; the first anode and the first cathode are both transparent electrodes.

17. The display device according to claim 16, wherein the glass substrate defines a first through hole that extends through opposite surfaces of the glass substrate; the display panel further comprises a conductive wire that passes through the first through hole and is electrically connected to the first light-emitting device and the second light-emitting device, respectively; the conductive wire extends in a direction perpendicular to the glass substrate and the silicon-based drive substrate, to reach the silicon-based drive substrate and be electrically connected to the silicon-based drive substrate.

18. The display device according to claim 17, wherein the second light-emitting device comprises a plurality of second subpixels; each of the plurality of second subpixels comprises a second anode, a second light-emitting layer, and a second cathode that are stacked in a direction of the glass substrate toward the silicon-based drive substrate; the second anode is a transparent electrode, the second cathode is a reflective electrode, and the second cathode is configured to reflect light beams emitted by the first light-emitting layer and the second light-emitting layer.

19. The display device according to claim 18, wherein the glass substrate defines a second through hole that extends through the opposite surfaces of the glass substrate; the second through hole is spaced apart from the first through hole, and the second through hole is filled with a conductive portion; the second cathode and the first cathode are electrically connected via the conductive portion.

20. A display panel, comprising:
a silicon-based drive substrate; and
a light-emitting substrate, connected to the silicon-based drive substrate; wherein the light-emitting substrate comprises:
a glass substrate;
a first light-emitting device, disposed on a side of the glass substrate away from the silicon-based drive substrate; and
a second light-emitting device, disposed between the silicon-based drive substrate and the glass substrate;
wherein the first light-emitting device comprises a plurality of first subpixels that are distributed in an array on the side of the glass substrate, and the second light-emitting device comprises a plurality of second subpixels that are distributed in an array on an opposite side of the glass substrate; the plurality of first subpixels and the plurality of second subpixels are arranged facing each other in a one-to-one correspondence;
wherein the silicon-based drive substrate is configured to simultaneously drive the first light-emitting device and the second light-emitting device, enabling the first light-emitting device and the second light-emitting device to emit light beams simultaneously.
